(19) United States
(12) Patent Application Publication
(10) Pub. No.: US 2023/0154953 A1
(43) Pub. Date: May 18, 2023

(54) COLOR IMAGE SENSOR AND MANUFACTURING METHOD THEREOF

(71) Applicant: Sensohub Co., Ltd., Anyang-si (KR)

(72) Inventor: Jeong-Hyong YI, Anyang-si (KR)

(21) Appl. No.: 17/983,904

(22) Filed: Nov. 9, 2022

(30) Foreign Application Priority Data
Nov. 16, 2021 (KR) 10-2021-0158082

(51) Int. Cl. H01L 27/146; H01L 23/544

(52) U.S. Cl. CPC H01L 27/14618; H01L 23/544; H01L 27/14683; G02B 5/201

(57) ABSTRACT

Provided is a color image sensor including: a silicon semiconductor chip housed in a package and having a plurality of pixels; an optical glass formed on an upper portion of the silicon semiconductor chip and having a color filter pattern formed thereon; and a window glass formed on the optical glass. According to embodiments of the present invention, color interference between neighboring pixels can be minimized, and the size of the silicon semiconductor chip can be designed smaller under the same color separation condition, which is economical.

### CROSS REFERENCE TO RELATED APPLICATIONS

The present application claims priority to Korean Patent Application No. 10-2021-0158082, filed Nov. 16, 2021, which is hereby incorporated herein by reference in its entirety.

### FIELD

Embodiments of the present invention relate to a color image sensor and a method of manufacturing the same, and more specifically, to a color image sensor in which a color filter is disposed in an upper portion of a pixel implemented in a silicon semiconductor chip to implement a color image signal, and a method of manufacturing the same.

### BACKGROUND

### Related Art

The above information disclosed in this Background section is only for enhancement of understanding of the background of the invention and therefore it may contain information that does not form the prior art that is already known in this country to a person of ordinary skill in the art.

Image sensors can be classified into line sensors in which pixel arrays are linearly arranged in one dimension and area sensors in which M×N pixels are arranged in a two-dimensional matrix. In general, as the number of pixels constituting the image sensor increases, high-resolution image quality is produced, and as the size of a unit pixel increases, the amount of light received increases, so that it is possible to provide image signals with good sensitivity.

Further, various techniques for implementing color image signals in an image sensor have been used. A color CCD or color CMOS image sensor converts a light signal, which has passed through a color filter, into an electrical signal by arranging patterns of color filters in a linear or mosaic manner in the upper area of a pixel that converts a light signal into an electrical signal.

Depending on the color image processing methods, it is common to use red (R), green (G), and blue (B) that are primary colors of light, yellow (Ye) and cyan (Cy), or green (Gr) and magenta (Mg) that are complementary colors to each other, for arrangement of a color filter. An infrared (IR) filter is sometimes added to implement a signal in an infrared area, but except for the colors and arrangement of the filters used, the circuit configuration for reading the color signals is similar.

Recently, there is a method of increasing the total number of pixels by reducing the size of the unit pixel in order to increase the resolution at the chip size of the same image sensor. In this case, however, since the amount of light that is received by the unit pixel is reduced, and thus, the sensitivity is lowered, the technique of providing a microlens over the filter area has already been used to compensate for the reduction in sensitivity.

In a silicon semiconductor image sensor, structures in which the color filters are arranged on the upper portion of (or over) each pixel may be largely divided into the method of directly forming an organic color filter on the surface of pixels of a silicon chip using a pigment or organic dye as a material through the semiconductor manufacturing process after the semiconductor process for manufacturing the image sensor is finished and the method of separately forming only a color filter on glass by deposition using an inorganic pigment and then aligning and forming the color filter in the pixel array in the packaging process.

Comparing the two methods, the method of directly forming a color filter of an organic material, on the surface of a silicon chip can protect the color filter from external contamination sources by performing the process in the same semiconductor manufacturing line, and since the method of directly forming a color filter is the same as the semiconductor chip manufacturing process, it is possible to minimize alignment error with the pixel.

However, since the manufacturing process is performed in the post-semiconductor process, the materials required for manufacturing a filter are generally manufactured in a low-temperature process. Therefore, when the environment in which the image sensor is used has a large temperature change, the filter layer is prone to cracking or warping, and the color filter layer is discolored over time. In addition, since the optical characteristic curve of the color filter of the organic material has a gentle bandwidth with respect to a light wavelength, there is a disadvantage in that color interference occurs between neighboring pixels.

Therefore, in a space environment with severe temperature change or when clear color separation between pixels is required, a dichroic filter manufactured by a high-temperature process using inorganic material is required. Usually, a color image sensor is implemented by the method of manufacturing a dichroic color filter on a separate glass and then aligning the dichroic color filter with pixels in the assembly process of sealing the image sensor chip with a package.

In the case of manufacturing a color image sensor by providing a color filter on glass, because of a physical gap that inevitably occurs between the surface of the pixel formed on the silicon chip and the glass of the color filter, the disadvantage that light that has passed through the color filter is refracted to affect neighboring pixels has been raised, and the distance between pixels needs to increase in the design stage, thereby causing the problem in that the size of the silicon chip increases.

### SUMMARY

Embodiments of the present invention provide an economical color image sensor and a method of manufacturing the same capable of minimizing color interference between neighboring pixels and designing a smaller size of a silicon semiconductor chip under the same color separation condition.

Embodiments of the present invention provide a color image sensor and a method for manufacturing the same capable of eliminating side effects due to refraction of light by minimizing a physical distance between optical glass and a surface of a pixel.

In one general aspect, a color image sensor includes: a silicon semiconductor chip housed in a package and having a plurality of pixels; an optical glass formed on an upper portion of the silicon semiconductor chip and having a pattern of a color filter formed thereon; and a window glass formed on an upper portion of the optical glass.

The optical glass and the window glass may be bonded through an alignment key or have a predetermined spacing.

The pattern of the color filter may be formed at a predetermined spacing from an upper portion of the pixel.

In the optical glass, the pattern of the color filter may be formed on a surface facing the silicon semiconductor chip, and an anti-reflective film may be formed on the other surface.

Other optical glass may be bonded to the optical glass.

The optical glass may be bonded to the other optical glass at a predetermined spacing, and at least one of these two optical glasses may be located below an upper portion of the package.

A color filter thin film may be formed on a surface of the optical glass, and the color filter thin film may be a thin film of a dichroic filter.

A passivation film may be attached to an upper portion of the image sensor chip, and the passivation film may have a predetermined distance from the optical glass or may be bonded to the optical glass, and when the passivation film is bonded to the optical glass, may be bonded via an alignment key that is disposed at one end and the other end between the optical glass and the passivation film.

A passivation film may be attached to the upper portion of the image sensor chip, and a distance between the color filters when the optical glass may not be attached to the passivation film is wider than that between the color filters when the optical glass is attached to the passivation film.

In another general aspect, a method of manufacturing a color image sensor may further include: housing a silicon semiconductor chip having a plurality of pixels in a package; bonding an optical glass having a pattern of a color filter formed on a window glass; and covering and sealing the window glass on an open surface of an upper portion of the package so that the optical glass is housed in the package.

In still another general aspect, a method of manufacturing a color image sensor may include: housing a silicon semiconductor chip having a plurality of pixels in a package; forming an optical glass having a pattern of a color filter formed thereon on an upper portion of the silicon semiconductor chip; and covering and sealing the window glass on an open surface of an upper portion of the package.

According to embodiments of the present invention, the color interference between neighboring pixels can be minimized, and the size of the silicon semiconductor chip can be designed smaller under the same color separation condition, which is economical.

According to embodiments of the present invention, by minimizing the physical distance between the optical glass and the surface of the pixel, it is possible to eliminate side effects due to the refraction of light.

### BRIEF DESCRIPTION OF THE DRAWINGS

FIG. 1A is a cross-sectional view illustrating a state in which a color image sensor according to one embodiment of the present invention is housed in a package.

FIG. 1B is a cross-sectional view illustrating a state in which a color image sensor according to one embodiment of the present invention is housed in a package.

FIG. 2 is a cross-sectional view of a color image sensor package in which a color filter having a width and a spacing is disposed on a surface of a conventional window glass.

FIG. 3 is a cross-sectional view of an on-chip color image sensor package in which a color filter is formed on a surface of a conventional silicon semiconductor chip.

FIG. 4 is a plan view of a color image sensor package window glass according to one embodiment of the present invention.

FIG. 5A is a plan view of an optical glass having a one-dimensional color pattern for implementing a color image sensor according to one embodiment of the present invention.

FIG. 5B is a plan view of an optical glass having a two-dimensional color pattern for implementing a color image sensor according to one embodiment of the present invention.

FIG. 6 is a plan view for explaining a state in which the window glass and the optical glass illustrated in FIG. 4 according to one embodiment of the present invention are aligned using an alignment key arranged on each of FIG. 5A, and then bonded to each other.

FIG. 7 is a plan view for explaining a state in which the window glass and the optical glass illustrated in FIG. 4 according to one embodiment of the present invention are aligned using the alignment key arranged on each of FIG. 5A and then bonded to each other.

FIGS. 8 to 12 are package cross-sectional views illustrating a package assembly process for implementing a color image sensor according to one embodiment of the present invention.

FIGS. 13 to 15 are cross-sectional views illustrating a color image sensor package assembly process corresponding to FIGS. 11 to 12 according to one embodiment of the present invention.

FIG. 16 is a cross-sectional view of a color image sensor package according to the structure of FIG. 2.

### DETAILED DESCRIPTION OF EXEMPLARY EMBODIMENTS

Advantages and features of the present disclosure and methods for accomplishing these advantages and features will become apparent from embodiments to be described later with reference to the accompanying drawings. However, the present invention may be modified in many different forms and it should not be limited to the exemplary embodiments set forth herein. Only the embodiments are provided to make the disclosure of the present invention complete, and to fully inform ordinary skill in the art to which the present invention belongs of the scope of the invention, and the present invention is defined only by the scope of the claims.

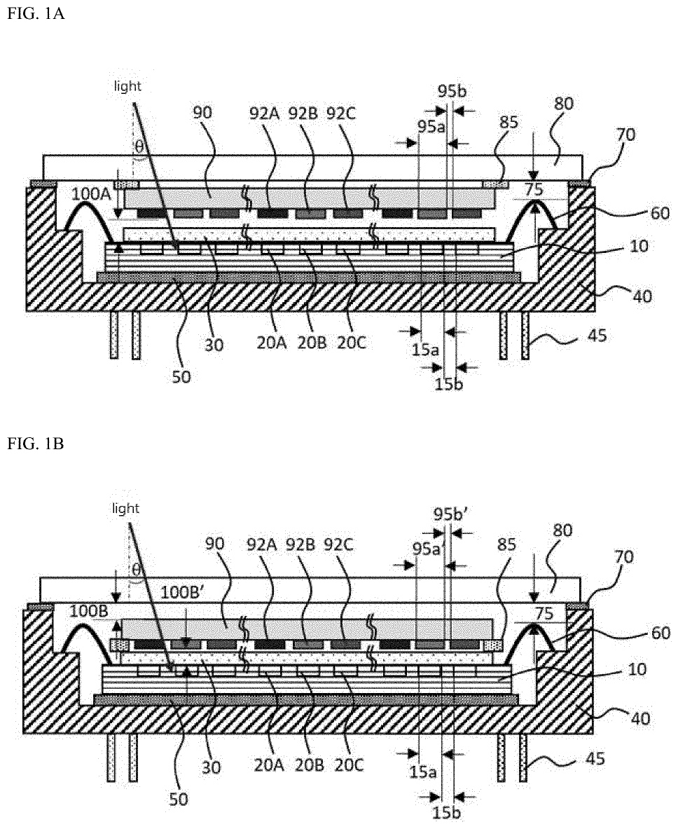

FIG. 1A is a cross-sectional view of a state in which a color image sensor according to one exemplary embodiment of the present invention is housed in a package, and FIG. 1B is a cross-sectional view of a state in which a color image sensor according to one exemplary embodiment of the present invention is housed in the package.

Referring to FIGS. 1A and 1B, the color image sensor may include a silicon semiconductor chip 10 that is housed in a package 40 and has a plurality of pixels 20A, 20B, and 20C, an optical glass 90 that is formed on an upper portion of (or over) the silicon semiconductor chip 10 and has patterns of color filters 92A, 92B, and 92C formed thereon, and a window glass 80 that is formed on an upper portion of the optical glass 90.

The color image sensor has a structure in which the optical glass (second optical glass 90) in which color filters are arranged is separately employed together with the window glass 80 (optical glass) used to transmit an optical signal to a pixel area of a silicon semiconductor chip while serving as a function of sealing a package in a typical image sensor package. Although the term “glass” is used in this specification, it is not necessarily limited to an inorganic material and may be an organic material capable of transmitting light, such as plastic.

Referring to FIG. 1A, the window glass 80 and the optical glass 90 are bonded via a predetermined alignment key 85, and the color filter maintains a predetermined distance 100A on a surface of a pixel. Referring to FIG. 1B, the window glass 80 and the optical glass 90 are separated from each other 100B at a predetermined spacing. In this case, the patterns of the color filters 92A, 92B, and 92C are formed at a predetermined spacing 100B′ from the upper portion of pixels 20A, 20B, and 20C.

In the optical glass 90, the patterns of the color filters 92A, 92B, and 92C are formed on a surface facing the silicon semiconductor chip 10, and an anti-reflective film is formed on the other surface thereof.

In addition, other optical glasses may be bonded to the optical glass 90. In this case, the optical glass 90 is bonded to the other optical glass at a predetermined spacing, and at least one of these two optical glasses may be located below the upper portion of the package 40.

In addition, a color filter thin film is formed on the surface of the optical glass 90, and the color filter thin film may be a dichroic filter thin film.

In addition, a passivation film 30 is attached to the upper portion of (or onto) the image sensor chip 10, and the passivation film 30 has a predetermined spacing from the optical glass 90 or is bonded to the optical glass 90, but when the passivation film 30 is bonded to the optical glass 90, the passivation film 30 may be bonded via an alignment key disposed at one end and the other end between the optical glass 90 and the passivation film 30.

In addition, the passivation film 30 is attached to the upper portion of (or onto) the image sensor chip 10, and a spacing between the color filters 92A, 92B, and 92C when the optical glass 90 is not attached to the passivation film 30 is wider than that between the color filters 92A, 92B, and 92C when the optical glass 90 is attached to the passivation film 30.

The structure of the color image sensor to be implemented in exemplary embodiments of the present invention will be described with reference to FIGS. 1A and 1B. The silicon semiconductor chip 10 manufactured by the conventional image sensor manufacturing technology using a silicon wafer is arranged in pixels 20A, 20B, and 20C for converting an optical signal into an electrical signal. One pixel is usually composed of a photodiode area 15a having a predetermined size for receiving an optical signal and an area 15b for separating from neighboring pixels.

Depending on the use of the image sensor, each unit pixel is two-dimensionally arranged in X and Y directions or one-dimensionally arranged in only one direction to form a silicon semiconductor chip. The color image sensor is implemented by disposing the color filters 92A, 92B, and 92C on the upper portions of (or over) the pixels 20A, 20B, and 20C. Depending on the method to be implemented, the arrangement and type of the color filters may be combined in various manners. The present invention will be described using R/G/B color patterns having a primary color arrangement.

In the final process step, the passivation film 30 for passivating the silicon semiconductor device area or a metal wiring is typically made on surfaces of all silicon semiconductor devices including an image sensor, and some area of the passivation film 30 is removed to form a metal wire 60 for electrically connecting to the outside. The silicon semiconductor chip 10 is housed and sealed inside the package 40 in various types, and a metal lead wire 45 for electrically controlling the silicon semiconductor chip sealed inside the package is disposed outside the package. The silicon semiconductor chip 10 and the package 40 have a structure connected by a metal wire 60.

Further, in the case of the image sensor, as a structural feature of a package that seals a silicon semiconductor chip, the surface of the package facing the upper portion of the surface of the silicon semiconductor chip on which the pixel is disposed is made in an open structure, and in the final step of the assembly process, the optical glass 80 called the window glass is sealed on the surface of the package 40 via a polymer resin or a photocatalyst resin 70, so the pixel may receive an optical signal.

When the light incident on the pixel is not incident on the surface of the silicon semiconductor chip perpendicular to the pixel, the light is affected by a refraction phenomenon while passing through the lens of the camera, the window glass, and an air layer in turn and is incident with a predetermined angle θ. Therefore, in the pixel design stage of the silicon semiconductor chip, the spacing 15b from the neighboring pixel is set in consideration of the refraction of light. In particular, in a structure in which the color filter layer has a distance from the pixel of the silicon semiconductor chip, a width 95a and a spacing 95b of the color pattern are also important design parameters.

FIGS. 1A and 1B illustrate a path through which light incident at a predetermined angle θ from a line perpendicular to the surface of the pixel reaches the surface of the pixel of the image sensor chip. Since a critical angle is a variable determined by the camera system, when employing the optical glass 90 with the distance from the surface of the pixel, the spacing 15b of the pixels and the spacing 95b of the color filter should be carefully set at the design stage so as not to affect neighboring pixels. In the case of bonding the window glass 80 and the optical glass 90 (FIG. 1A), it is indicated that the spacing 95b of the filter area should be designed to be wider than the filter spacing 95b′ when attaching the optical glass 90 to the passivation film 30 of the image sensor chip 10.

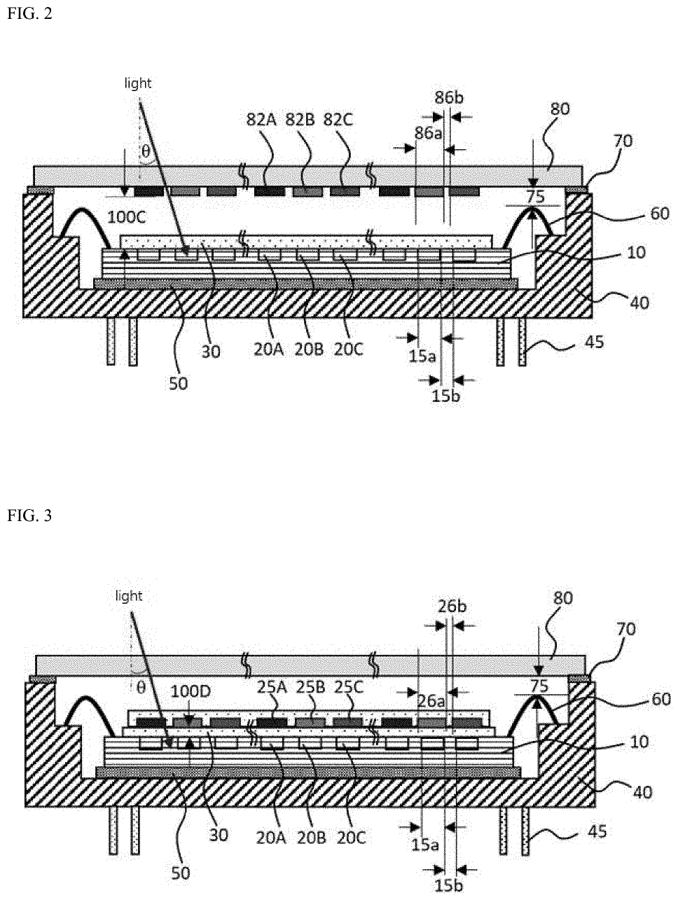

FIG. 2 is a cross-sectional view of a color image sensor package in which a color filter having a width and a spacing is disposed on a surface of a conventional window glass.

In the typical image sensor package structure, the lower surface of the window glass 80 and the pixel of the silicon semiconductor chip 10 are separated by a predetermined distance 100C. This is because when the silicon semiconductor chip and the package are usually connected by the metal wire 60, they have an upwardly protruding shape, so the lower surface of the window glass 80 should be maintained at a minimum spacing 75 or more without physical contact with the metal wire. According to the structure illustrated in FIG. 2, since the distance 100C between the pixel and the filter layer disposed on the window glass 80 is longer than the distance 100A in the structure illustrated in FIG. 1A and the distance 100B in the structure illustrated in FIG. 1B which is the embodiment of the present invention, the incident light affects neighboring pixels, thereby causing color interference.

FIG. 3 is a cross-sectional view of an on-chip color image sensor package in which a color filter is formed on a surface of a conventional silicon semiconductor chip.

Referring to FIG. 3, since a distance 100D between the color filter and the pixel is about a thickness of the passivation film 30 formed on the surface of the pixel, from the viewpoint of the color interference, it is the most effective method among the techniques listed in one embodiment of the present invention. Since the height of the package 40 may also be manufactured to a minimum, it is a very effective structure for a mobile product with a small pixel size 15a and pixel spacing 15b. The size 26a and spacing 26b of the color filters 25A, 25B, and 25C may be manufactured to the same extent as the size 15a and spacing 15b of the pixel. However, since high reliability is required for large image sensors for industrial machine vision or image sensors intended for use in space environments such as satellites, it is difficult to apply organic dyes to on-chip color filters manufactured in a typical semiconductor manufacturing process environment. Therefore, a method of manufacturing a pattern of a color filter using an inorganic dye on the window glass 80 is required.

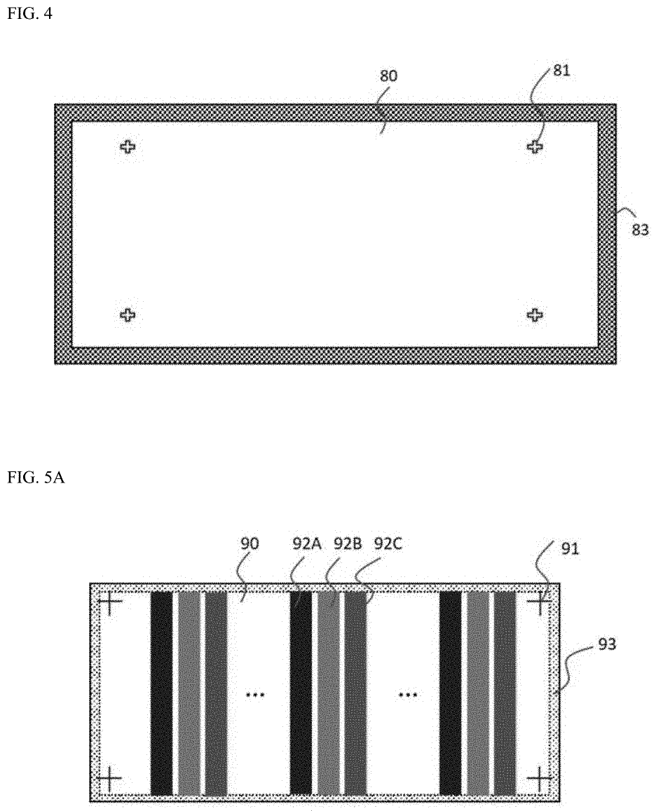

Hereinafter, a method of manufacturing a color image sensor according to one embodiment of the present invention will be described with reference to FIGS. 4 to 12.

FIG. 4 is a plan view of a color image sensor package window glass according to one embodiment of the present invention.

FIG. 4 shows a plan view of the window glass 80, which is an essential material in the image sensor package structure. In the typical image sensor package, the light transmittance characteristic for effectively transmitting light is important, and an anti-reflective coating treatment is sometimes added to the upper portion of (or onto) the pixel area to control reflected light. In FIG. 4, it can be seen that a key pattern 81 for alignment is required because the color filter is disposed on the optical glass 90 separate from the window glass 80. In general, an adhesive application area 83 for bonding to the upper portion of (or onto) the package is separately provided on the window glass by using a polymer resin or a photocatalyst resin 70 as an adhesive.

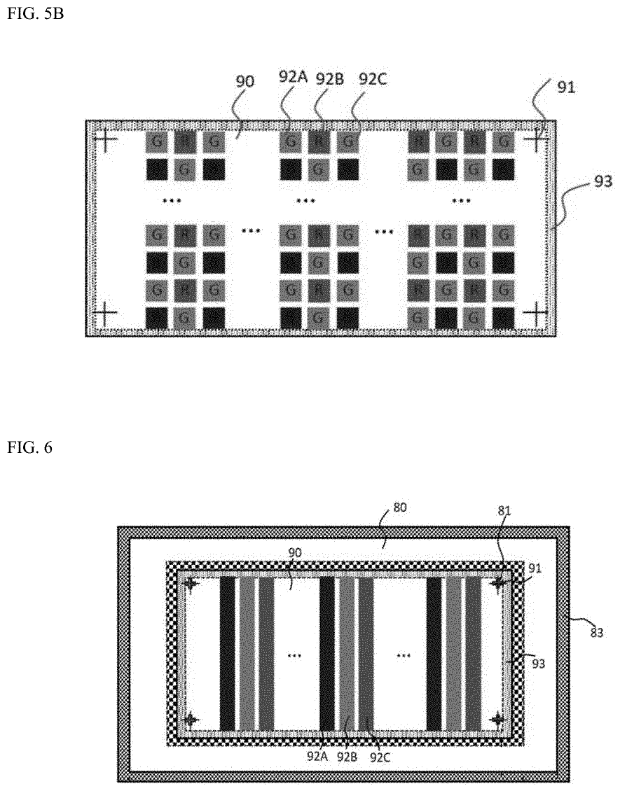

FIG. 5A is a plan view of an optical glass having a one-dimensional color pattern for implementing a color image sensor according to one embodiment of the present invention, and FIG. 5B is a plan view of an optical glass having a two-dimensional color pattern for implementing a color image sensor according to one embodiment of the present invention.

FIGS. 5A and 5B correspond to plan views of the optical glass 90. Since the optical glass 90 has a structure housed in the package space below the window glass 80, the size of the optical glass is manufactured to be smaller than that of the window glass 80. Depending on the structure of the image sensor, the color filters 92A, 92B, and 92C may have a linear arrangement as illustrated in FIG. 5A or an array arrangement as illustrated in FIG. 5B. Here, it will be described using the structure of FIG. 5A as an example. However, the content of embodiments of the present invention are not limited to a specific color filter arrangement method.

The optical glass 90 has an alignment key pattern 91 corresponding to the alignment key pattern 81 disposed on the window glass 80 as illustrated in FIG. 4, and the alignment key pattern 91 disposed on the optical glass 90 may also correspond to the alignment key pattern designed for the silicon semiconductor chip 10. The border of the optical glass 90 has a structure that serves to prevent the adhesive from invading into the filter pattern area by restricting an area 93 for applying the adhesive when the window glass 80 is bonded.

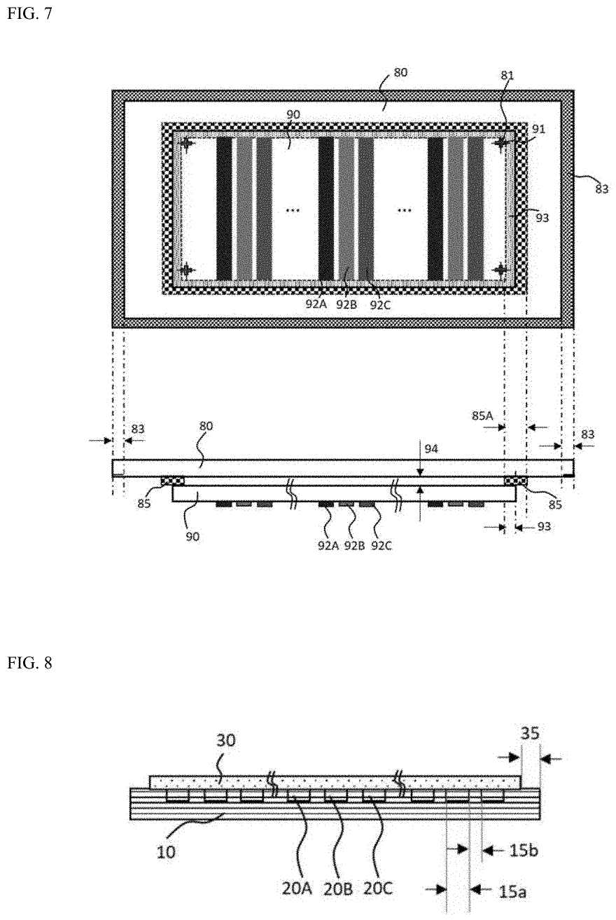

FIG. 6 is a plan view for explaining a state in which the window glass and the optical glass illustrated in FIG. 4 according to one embodiment of the present invention are aligned using alignment keys each arranged on FIG. 5A, and then bonded to each other. FIG. 7 is a plan view for explaining a state in which the window glass and the optical glass illustrated in FIG. 4 according to one embodiment of the present invention are aligned using the alignment keys each arranged in FIG. 5A and then bonded to each other. [symbol] 6 and 7, a plan view and a cross-sectional view after bonding the window glass 80 of FIG. 4 and the optical glass 90 of FIG. 5A using the alignment key patterns 81 and 91, respectively.

FIGS. 6 and 7 each illustrate a plan view and a cross-sectional view of the window glass 80 of FIG. 4 and the optical glass 90 of FIG. 5A that are bonded through the alignment key pattern 85.

The window glass 80 and the optical glass 90 may be used via the alignment key pattern 85 having a predetermined thickness as a medium, and may be manufactured using the polymer resin. The width 85A of the area bonded to the window glass 80 by applying a polymer resin is formed larger than a border area 93 designed for the optical glass 90 because the two glasses are bonded using a pressing jig. However, it should be considered in the design stage of the color filter pattern of the optical glass 90 so as not to invade the inside of the filter area.

FIGS. 8 to 10 are cross-sectional views illustrating a manufacturing process for housing the silicon semiconductor chip 10 in the image sensor exclusive package 10.

FIGS. 8 to 12 are package cross-sectional views illustrating a package assembly process for implementing a color image sensor according to one embodiment of the present invention.

FIG. 8 illustrates a cross-sectional view of a silicon image sensor chip in the form in which a wafer is selected and separated into pieces. FIG. 8 illustrates that pixels 20A, 20B, and 20C that respond to light are disposed on the silicon semiconductor chip 10 and a unit pixel has an area with a predetermined width 15a and a separated line width 15b. It is illustrated that the front surface of the pixel area is covered with the passivation film 30. Typically, in the last step of the semiconductor manufacturing process, after the passivation film 30 is formed on the entire wafer surface using a nitride film or an oxide film to protect the silicon surface from contamination sources, the passivation film on a specific area (usually called a pad 35) is removed by an etching method. The pad area 35 of the silicon semiconductor chip 10 from which the passivation film has been removed by etching serves to connect the pad area of the package by a metal wire in the package assembly step, so the electric signal may be applied from the outside of the package.

After the semiconductor manufacturing process is finished, the silicon semiconductor chip, which is completed in a wafer state, undergoes an electrical test process, a good product selection process, and then is separated into pieces and put into the assembly process. The silicon semiconductor chip 10 illustrated in FIG. 8 is in a state in which the wafer is separated into pieces after being selected as good products.

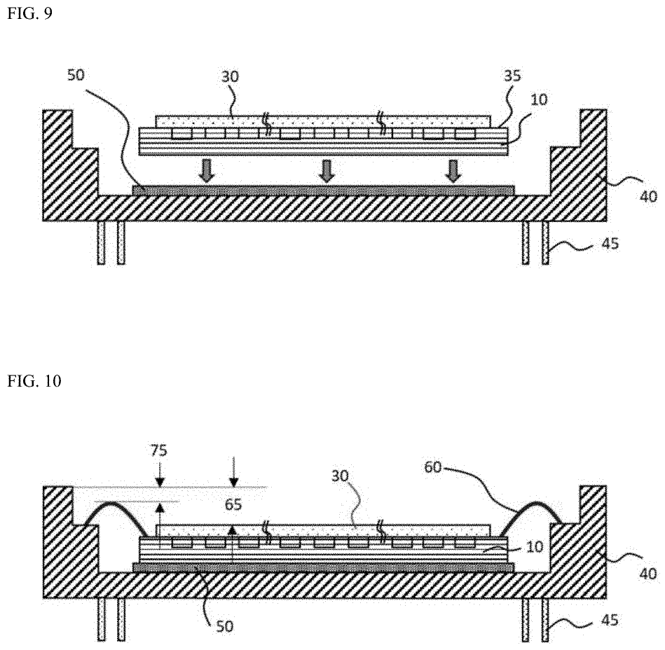

FIG. 9 illustrates a step of housing the silicon semiconductor chip 10, which is selected as good products from the wafer and separated into pieces, in a package. FIG. 9 illustrates a process of applying a polymer resin 50 to one surface of the package to a uniform thickness, aligning the silicon semiconductor chip 10 with the package, and then curing the silicon semiconductor chip 10 with heat in a specific high temperature atmosphere. FIG. 9 is a cross-sectional view illustrating a die bonding process commonly called in the package assembly process. In the shape of the package 40 for accommodating the silicon semiconductor chip 10, the upper portion of the image sensor chip has an open package surface.

FIG. 10 illustrates a cross-sectional view of the package subjected to the process called wire bonding, which connects the package pad and the image sensor pad area with the metal wire 60 during the package assembly process. In general, since the metal wire 60 has an upwardly protruding shape, it is important to secure at least a predetermined distance 75 by designing the package body higher than the height of the shape in which the metal wire bonding process is completed. Therefore, after the metal wire connection process is completed, a predetermined spacing 65 is automatically generated between the surface of the passivation film 30 of the silicon semiconductor chip and the uppermost layer of the package 40. In the semiconductor products other than the color image sensor, a plastic resin is usually filled and sealed, but in the color image sensor package, the space between the silicon semiconductor chip 10 and the window glass 80 of the upper portion is empty.

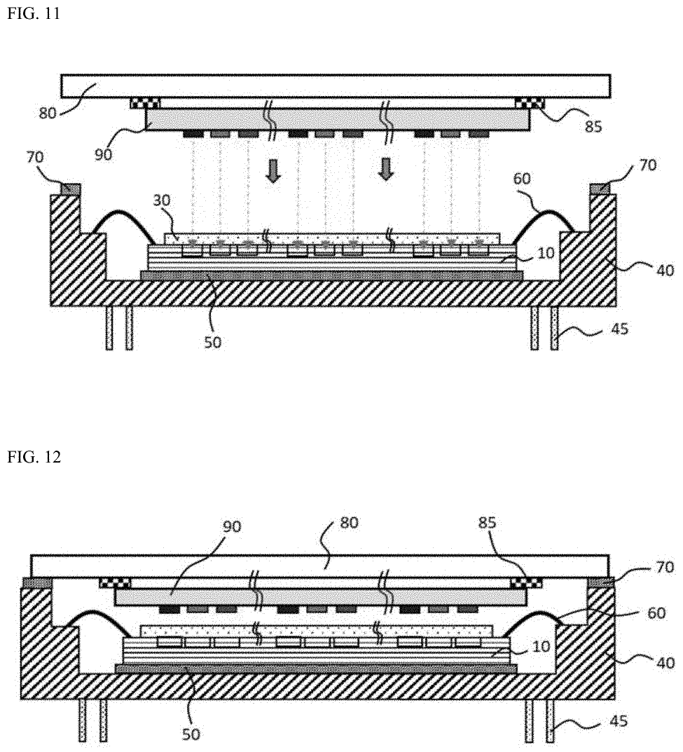

FIG. 11 illustrates a process of sealing the open package surface with optical glass in the color image sensor package process. A high molecular resin or UV-reactive curing resin 70 is applied to a predetermined area of the upper portion of the package 40 to a predetermined width and thickness. FIG. 1A illustrates the process of aligning the pixel arrangement and the color filter arrangement of the optical glass of the silicon semiconductor chip 10 on the upper portion of the package on which the metal wire connection process described with reference to FIG. 10 is completed by combining the window glass 80 and the optical glass 90 described in FIGS. 6 and 7, and illustrates that the pixel of the silicon semiconductor chip 10 and the filter pattern of the optical glass 90 are arranged to correspond to each other, respectively.

FIG. 12 illustrates a cross-sectional view of the completed color image sensor package for the structure of FIG. 1. FIG. 12 illustrates the arrangement state of the image sensor chip 10, the optical glass 90, and the window glass 80 in the package 40 space. The spacing between the optical glass 90 and the color filter and the upper portion passivation film of the silicon semiconductor chip may be arranged as a minimum spacing according to the shape height of the package metal wire 60 and the thickness and size design of the optical glass.

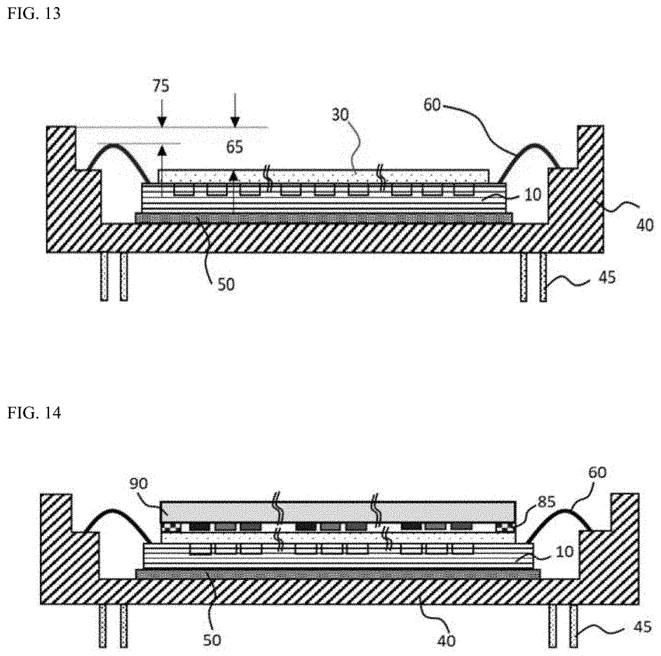

FIG. 13 illustrates, as the process corresponding to FIG. 11 described in the structure of FIG. 2, a cross-sectional view of the package assembly process in which, after the connection process of the metal wire 60 of the typical color image sensor assembly process described in FIG. 10, the optical glass 90 is first inserted into a specific area on the passivation film 30, only the polymer resin (epoxy) is used, and the color filter arrangement of the optical glass 90 is aligned and bonded to the pixel array of the silicon semiconductor chip 10. In the case of using the alignment key, a process of fixing upper and lower surfaces of a support using a polymer resin is added.

FIG. 14 illustrates a cross-sectional view of the structure in which the optical glass 90 is brought into close contact with the passivation film 30 of the upper portion of the silicon semiconductor chip as much as possible through the alignment key 85 or the polymer resin or the optical glass 90 is bonded to the passivation film 30 by aligning the pixel array and the color filter array with a minimum spacing. Since the arrangement of the metal wire 60 connecting the pad area of the image sensor chip and the package pad area needs to be considered, in FIG. 2, a size constraint of the optical glass 90 occurs, and the size of the optical glass 90 should be smaller than the inside of the pad area of the silicon semiconductor chip 10.

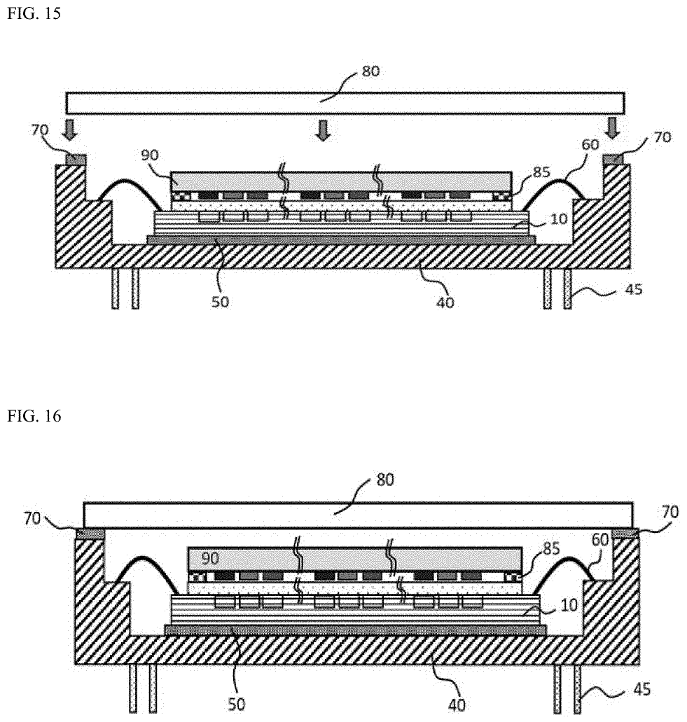

FIG. 15 is a cross-sectional view illustrating a process of covering and sealing the window glass 80 on the open surface of the upper portion of the package in FIG. 2. It is the same method as the sealing of the window glass 80 performed in the conventional color image sensor package, and the difference is that the silicon semiconductor chip 10 in the inner space of the package and the optical glass 90 in the upper portion thereof exist together. A corresponding process is illustrated by aligning the predetermined area 83 designed on the window glass 80 described in FIG. 4 and the polymer resin application area after the window glass 80 and the predetermined area of the upper portion of the package 40 are applied to a predetermined thickness of a polymer resin (epoxy) that normally responds to UV rays in a predetermined area.

FIG. 16 is a cross-sectional view of a color image sensor package according to the structure of FIG. 2.

In FIG. 16, compared with the structure of FIG. 1, the distance between the optical glass 90 and the window glass 80 is larger, but it is possible to maintain the distance between the color filter of the optical glass 90 and the pixel of the silicon semiconductor chip 10 to a minimum.

Although the present invention has been described with reference to exemplary embodiments shown in the accompanying drawings, it is only an example. It will be understood by those skilled in the art that various modifications and equivalent other exemplary embodiments are possible from the present invention. Accordingly, an actual technical protection scope of the present invention is to be defined by the technical spirit of the following claims.

1. A color image sensor, comprising:
a silicon semiconductor chip housed in a package and having a plurality of pixels;
an optical glass formed on the silicon semiconductor chip and having a pattern of a color filter formed thereon; and
a window glass formed on the optical glass.

2. The color image sensor of claim 1, wherein the optical glass and the window glass are bonded through an alignment key or have a predetermined spacing.

3. The color image sensor of claim 1, wherein the pattern of the color filter is formed at a predetermined spacing from an upper portion of the pixel.

4. The color image sensor of claim 1, wherein, in the optical glass, a pattern of a color filter is formed on a surface facing the silicon semiconductor chip, and an anti-reflective film is formed on the other surface.

5. The color image sensor of claim 1, wherein other optical glass is bonded to the optical glass.

6. The color image sensor of claim 5, wherein the optical glass is bonded to the other optical glass at a predetermined spacing, and at least one of these two optical glasses is located below an upper portion of the package.

7. The color image sensor of claim 1, wherein a color filter thin film is formed on a surface of the optical glass, and the color filter thin film is a thin film of a dichroic filter.

8. The color image sensor of claim 1, wherein a passivation film is attached to the image sensor chip, and the passivation film has a predetermined distance from the optical glass or is bonded to the optical glass, and when the passivation film is bonded to the optical glass, is bonded via an alignment key that is disposed at one end and the other end between the optical glass and the passivation film.

9. The color image sensor of claim 1, wherein a passivation film is attached to the upper portion of the image sensor chip, and a distance between the color filters when the optical glass is not attached to the passivation film is wider than that between the color filters when the optical glass is attached to the passivation film.

10. A method of manufacturing a color image sensor, comprising:
housing a silicon semiconductor chip having a plurality of pixels in a package;
bonding an optical glass having a pattern of a color filter formed on a window glass; and
covering and sealing the window glass on an open surface of an upper portion of the package so that the optical glass is housed in the package.

11. The method of claim 10, wherein the optical glass and the window glass are bonded through an alignment key or have a predetermined spacing.

12. The method of claim 10, wherein the pattern of the color filter is formed at a predetermined spacing from an upper portion of the pixel.

13. The method of claim 10, wherein, in the optical glass, the pattern of the color filter is formed on a surface facing the silicon semiconductor chip, and an anti-reflective film is formed on the other surface.

14. A method of manufacturing a color image sensor, comprising:
housing a silicon semiconductor chip having a plurality of pixels in a package;
forming an optical glass having a pattern of a color filter formed thereon on an upper portion of the silicon semiconductor chip; and
covering and sealing the window glass on an open surface of an upper portion of the package.

15. The method of claim 14, wherein the optical glass and the window glass are bonded through an alignment key or have a predetermined spacing.

16. The method of claim 14, wherein the pattern of the color filter is formed at a predetermined spacing from an upper portion of the pixel.

17. The method of claim 14, wherein, in the optical glass, the pattern of the color filter is formed on a surface facing the silicon semiconductor chip, and an anti-reflective film is formed on the other surface.
